(19) United States
(12) Patent Application Publication
(10) Pub. No.: US 2008/0122069 A1
(43) Pub. Date: May 29, 2008

(54) Heat sink

(76) Inventor: Yu-Sheng Chen, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/976,774

(22) Filed: Oct. 29, 2007

(30) Foreign Application Priority Data
Nov. 23, 2006 (CN) 200620067998.8

(51) Int. Cl. H01L 23/36

(52) U.S. Cl. 257/712; 257/E23.101

(57) ABSTRACT

A heat sink is used to dissipate the heat of a chip module with a first bump and a second bump. The first bump is located centrally on the chip module and the second bump is disposed laterally at a distance from of the first bump, and the heat sink has a contact surface, a first cavity and a second cavity containing the first bump and the second bump respectively.

The first cavity and the second cavity not only position tightly the heat sink onto the chip module but also conduct heat efficiently from the chip module to the heat sink and to protect electronic elements disposed on the chip module. The heat-dissipating efficiency of the heat sink is increased, and production costs are reduced as additional elements for clamping the heat sink onto the chip module are made redundant.

### BACKGROUND OF THE INVENTION

1. Field of the invention

The present invention relates to a heat sink.

2. Description of the Prior Art

The rapid development of integrated circuit technology has lead to a vastly increased processing speed, and as a side effect has also increased the amount of heat produced by the chip modules in which these circuits are embedded for computer applications. Hence, it is an important task to improve the heat-dissipating efficiency of heat sinks as well as to reduce their working temperature.

Please refer to FIG. 1 which is a schematic view of a heat sink and a chip module of the prior art. A chip module 20a is in contact with a glossy bottom surface 11a of a heat sink 10a. The chip module 20a comprises a chip housing 21a which is clamped onto the bottom surface 11a of the heat sink 10a by means of clamping components (not shown), such as an iron shell, a pressing spring, and etc. so as to dissipate the heat generated by the chip module 20a. However, the chip housing 21a of the chip module 20a can move laterally (not shown) with respect of the bottom surface 11a of the heat sink 10a as there is no lateral fixture between the heat sink 10a and the chip module 20a. In this case, i.e. when the chip housing 21a is not aligned with the heat sink 10a, the performance of the heat sink decreases as it is not pressed uniformly against the chip housing 21a. In addition, the use of clamping components for fixing the chip module 20a to the heat sink 10a adds to the production costs.

The inventor of the present invention is aware of the above described shortcomings and has devoted special efforts to the research of this field. As a result, the present invention is presented, which effectively resolves the above mentioned problems.

### SUMMARY OF THE INVENTION

It is a primary object of the present invention to provide a heat sink that increases dissipation of the heat generated by the chip module while decreasing production costs.

For achieving the objectives stated above, a heat sink for a chip module is proposed with a first cavity and a second cavity, the first cavity being located centrally at the heat sink and the second cavity being located laterally at a distance from the first cavity, and the chip module having two bumps that tightly fit into the two cavities. Furthermore, the heat sink has a contact surface and a pressing area in contact with the chip module.

By comparison to the prior art, the heat sink is locked in a central position above the processing unit and heat is effectively transmitted from the processing unit to the heat sink through the contact areas as well as through the pressing area within the first cavity that presses against the first bump. The cavities on the heat sink have the additional effect of protecting the electronic elements within the chip module. Furthermore, production costs are decreased compared to the prior art as there are no additional clamping elements necessary to attach the heat sink to the chip module.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The above and further advantages of this invention may be better understood by referring to the following description, taken in conjunction with the accompanying drawings, in which:

FIG. 1 is a schematic view of a heat sink assembled with a chip module in the prior art;

FIG. 2 is a schematic view of the assembly of a heat sink and a chip module according to one embodiment of the present invention;

FIG. 3 is a schematic view of a heat sink according to one embodiment of the present invention; and

FIG. 4 is a schematic view of the chip module according to one embodiment of the present invention.

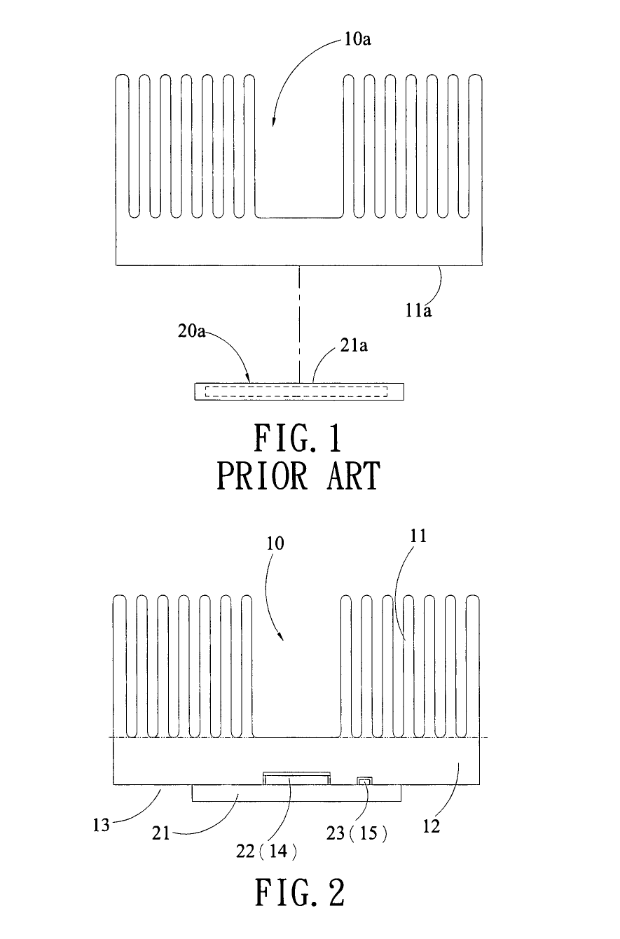

The drawings will be described further in connection with the following Detailed Description of the Invention.

### DETAILED DESCRIPTION OF THE PREFERRED EMBODIMENTS

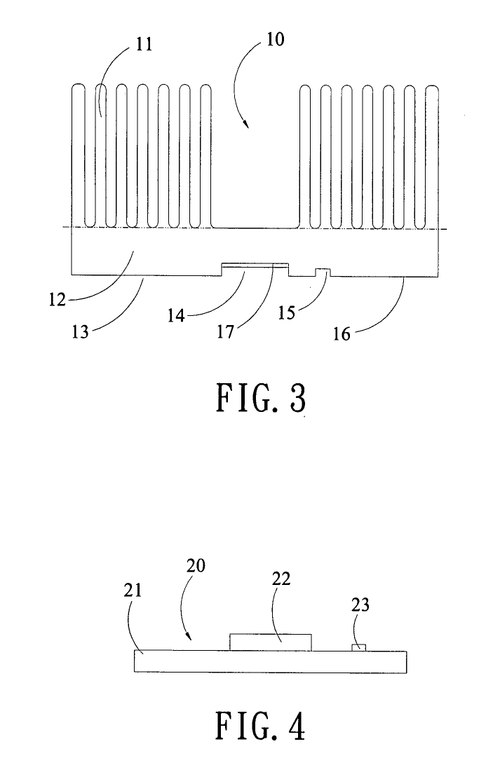

Please refer to FIG. 2 to FIG. 4. A heat sink 10 is used to dissipate the heat of a chip module 20. It comprises a heat-dissipating portion 11 and a base 12 disposed under the heat-dissipating portion 11. The base 12 can be integrally formed with the heat-dissipating portion 11 or can be connected with the heat-dissipating portion 11 via a viscose or a fixing device (not shown). The base 12 has a contact surface 13, a first cavity 14, a second cavity 15 and a contact area 16 formed on the contact surface 13. The cavities 14 and 15 are grooves. The first cavity 14 is disposed centrally at the base 12 and the second cavity 15 is disposed laterally at a distance from the first cavity 14, and the second cavity 15 is smaller then the first cavity 14. The first cavity 14 contains a buffer element 17 which is made of elastic or dense heat conductive material.

The chip module 20 comprises a housing 21, and a first and a second bump 22 and 23 installed on housing 21. The first bump 22 is centrally located on the housing 21, and the second bump 23 is an electronic element installed laterally at a distance from the first bump 22.

The first and second bump 22 and 23 are fitting into the first and second cavity 14 and 15, respectively, of the heat sink 10, thus creating a tight fit between heat sink 10 and chip module 20. During assembly the heat sink 10 is pressed against the chip module 20 and the contact area 16 of the heat sink 10 comes into tight contact with the housing 21. Due to the first bump 22 and the first cavity 14 being located centrally on the housing 21 and the base 12, respectively, the pressure is distributed evenly during the assembly of the heat sink 10 with the chip module 20. Also, besides being a heat conductor, the buffer element 17 in the first cavity 14 protects the chip module 20 from shocks induced by the heat sink 10. Furthermore, the second cavity 15 of the heat sink 10 protects the electronic element installed on the chip module 20 from being crushed.

Although the present invention has been described with reference to the preferred embodiment thereof, it shall be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat sink to dissipate the heat of a chip module, comprising a contact surface with a first cavity and a second cavity, wherein the chip module comprises a first bump and a second bump, the first cavity and the second cavity engages with the first bump and the second bump on the chip module, respectively.

2. The heat sink as claimed in claim 1, wherein the contact surface contains a contact area.

3. The heat sink as claimed in claim 2, wherein the chip module has a housing contacting the contact area of the heat sink.

4. The heat sink as claimed in claim 3, wherein the first bump is located centrally on the housing.

5. The heat sink as claimed in claim 3, wherein the second bump is an electronic element disposed on the housing.

6. The heat sink as claimed in claim 1, wherein the first cavity contains a buffer element.

7. The heat sink as claimed in claim 1, wherein the heat sink comprises a heat-dissipating portion and a base disposed under the heat-dissipating portion.

8. The heat sink as claimed in claim 7, wherein the first cavity is located centrally on the base.

9. The heat sink as claimed in claim 7, wherein the heat-dissipating portion is integrally formed with the base.

10. The heat sink as claimed in claim 7, wherein the heat-dissipating portion and the base are connected by a fixing device.

11. A heat sink to dissipate the heat of a chip module with a first cavity and a second cavity, engaging with a first bump and a second bump on the chip module, respectively, the heat sink having a contact surface, the first bump and the first cavity being located centrally on the chip module and the contact surface, respectively, and the second cavity and the second bump being disposed laterally at a distance from the first cavity and the first bump, respectively.
